(19) United States
(12) Patent Application Publication
(10) Pub. No.: US 2010/0134135 A1
(43) Pub. Date: Jun. 3, 2010

(54) Semiconductor device test apparatus

(75) Inventor: Jong-Pil Park, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/588,901

(22) Filed: Nov. 2, 2009

(30) Foreign Application Priority Data
Dec. 2, 2008 (KR) 10-2008-0120904

(51) Int. Cl. G01R 31/26

(52) U.S. Cl. 324/765

(57) ABSTRACT

A semiconductor device test apparatus may include a test handler using a customer tray and a test tray to sequentially transport a plurality of semiconductor devices to a loading part, a soak part, a test part, a desoak part, and an unloading part; and a test head electrically connected to the semiconductor devices in the test tray disposed in the test part to test electrical characteristics of the semiconductor devices. The test part is provided in the test handler such that the test tray is on an upper surface of the test handler. The test head is provided above the test handler such that a lower surface thereof having a test socket provided thereon faces the test part. The semiconductor devices in the test tray disposed in the test part of the test handler are electrically connected to the test socket by a downward movement of the test head.

### CROSS-REFERENCE TO RELATED APPLICATIONS

This application claims priority under 35 U.S.C. §119 to Korean Patent Application No. 2008-0120904, filed on Dec. 2, 2008, in the Korean Intellectual Property Office (KIPO), the entire contents of which are incorporated herein by reference.

### BACKGROUND

1. Field

Example embodiments relate to a semiconductor device test apparatus for testing electrical characteristics of a semiconductor device, and more particularly, to a semiconductor device test apparatus capable of stably and accurately testing semiconductor devices having a relatively small thickness, a relatively small size, and a relatively light weight.

2. Description of the Related Art

Electrical tests may be performed on a processed semiconductor device, before shipment, in order to check whether there are defects in the semiconductor device.

A conventional test apparatus for testing a semiconductor device includes a test handler that transports the semiconductor device to be tested. The test handler transports a test tray having the semiconductor device loaded thereon. The test handler moves the test tray to a test position for testing. At the test position, leads or balls, which are external connection terminals of the semiconductor device loaded on the test tray, are electrically connected to a socket of the test head and a predetermined electrical test is performed on the semiconductor device.

The performance of semiconductor devices has been improved and the size thereof has been reduced. In addition, the number of external connection terminals of the semiconductor devices has increased, and the gap between the external connection terminals has been reduced.

The test handlers according to the related art are classified into a horizontal docking structure and a vertical docking structure according to a movement direction of a test head for connection with a corresponding test handler. In the related art, it is necessary to provide a structure for preventing the detachment of the semiconductor devices from the test tray in the test handler having the horizontal docking structure or the vertical docking structure.

In addition, as the number of external connection terminals of the semiconductor device is increased and the gap between the external connection terminals is reduced, the area of the test tray required to clamp the semiconductor devices is reduced, which may result in a clamping error. The clamping error of the semiconductor device in the test tray may cause an error in the connection between the test handler and the test head at the test position. As a result, test efficiency may be lowered.

Some conventional test apparatuses allow for a large number of semiconductor devices to be tested at the same time in order to improve the test efficiency of the semiconductor devices per hour. Therefore, in the related art, a test tray capable of accommodating a large number of semiconductor devices is required.

It is inevitable to increase the size of the test head in order to apply a large number of electric signals to the semiconductor devices. However, in order to increase the size of the test head, it is necessary in the horizontal docking structure to increase the size of the test handler while extending a space for inserting the test head, and it is necessary in the vertical docking structure to increase the size of the test head provided outside the test handler. As a result, the overall mounting space between the test handler and the test head is increased, which is uneconomic.

### SUMMARY

Example embodiments provide a semiconductor device test apparatus capable of accurately connecting to external connection terminals of a relatively small semiconductor device to stably test the semiconductor device while minimizing or reducing variation in the structure of a test tray. In accordance with example embodiments, the semiconductor device test apparatus may accurately connect to the external connection terminals of the semiconductor device even when the external connection terminals have a relatively small gap there between. Example embodiments also provide a semiconductor device test apparatus capable of testing a relatively large number of semiconductor devices at the same time without little to no increase in the size and install space of facilities. Example embodiments also provide a semiconductor device test apparatus that may be capable of simplifying a structure of a test tray in which semiconductor devices to be tested are accommodated.

According to example embodiments, a semiconductor device test apparatus may include a test handler using a customer tray and a test tray to sequentially transport a plurality of semiconductor devices to a loading part, a soak part, a test part, a desoak part, and an unloading part. The example semiconductor device test apparatus may also include a test head electrically connected to the semiconductor devices in the test tray disposed in the test part of the test handler to test the electrical characteristics of the semiconductor devices. The test part in which the semiconductor devices are tested may be provided in the test handler such that the test tray is disposed in the test part on an upper surface of the test handler. The test head may be provided above the test handler such that a lower surface thereof having a test socket provided thereon faces the test part. The plurality of semiconductor devices accommodated in the test tray disposed in the test part of the test handler may be electrically connected to the test socket by a downward movement of the test head.

In accordance with example embodiments, the lower surface of the test socket and the upper surface of the test part of the test handler may be horizontal planes.

In accordance with example embodiments, the lower surface of the test socket and the upper surface of the test part of the test handler may be inclined at the same angle.

As described above, the test head may be provided above the test handler and may be connected to the test handler in an over docking manner. In addition, a plurality of semiconductor devices may be stably aligned in the test tray disposed in the test part on the upper surface of the test handler such that the semiconductor devices are electrically connected to the test socket of the test head above the test tray accurately. In this way, a test may be stably performed.

Further, it is possible to improve test efficiency without extending the mounting space of the test handler and the test head in plan view even when the area of the test tray is increased in order to test a large number of semiconductor devices at the same time and the size of the test head facing the test tray is increased.

The structure of the test handler in which the test part is provided on the upper surface thereof may be simply improved, and the existing test head may be used without any change. Therefore, the semiconductor device test apparatus may have high compatibility.

### BRIEF DESCRIPTION OF THE DRAWINGS

Example embodiments will be more clearly understood from the following brief description taken in conjunction with the accompanying drawings. FIGS. 1 to 7 represent non-limiting, example embodiments as described herein.

FIG. 1 is a perspective view schematically illustrating the overall structure of a semiconductor device test apparatus according to example embodiments;

FIG. 2 is a side view illustrating the semiconductor device test apparatus shown in FIG. 1, as viewed from one side;

FIG. 3 is a block diagram illustrating the path through which semiconductor devices are moved in a test handler according to example embodiments;

FIG. 4 is a perspective view schematically illustrating the overall structure of a semiconductor device test apparatus according example embodiments;

FIG. 5 is a side view illustrating the semiconductor device test apparatus shown in FIG. 4, as viewed from one side;

FIG. 6 is a partial enlarged view illustrating semiconductor devices accommodated and aligned in a test tray in the structure shown in FIG. 4; and

FIG. 7 is a partial enlarged view illustrating an example of the test tray applicable to the semiconductor device test apparatus according to example embodiments.

It should be noted that these figures are intended to illustrate the general characteristics of methods, structure and/or materials utilized in example embodiments and to supplement the written description provided below. These drawings are not, however, to scale and may not precisely reflect the precise structural or performance characteristics of example embodiments, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements that may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, semiconductor device test apparatuses according to example embodiments will be described in detail with reference to the accompanying drawings.

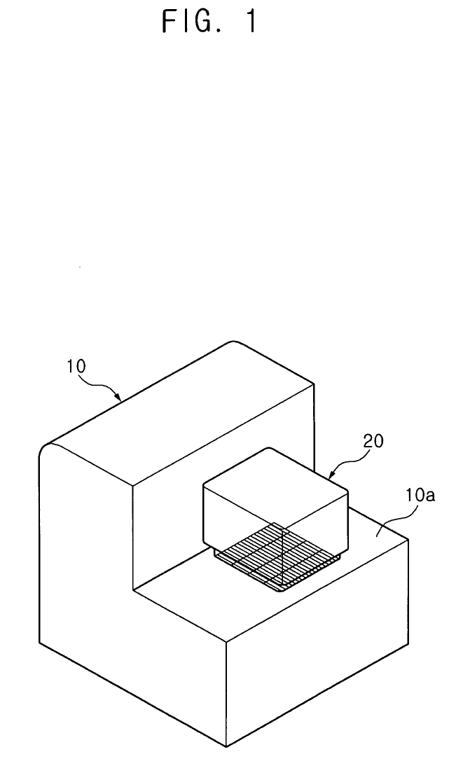

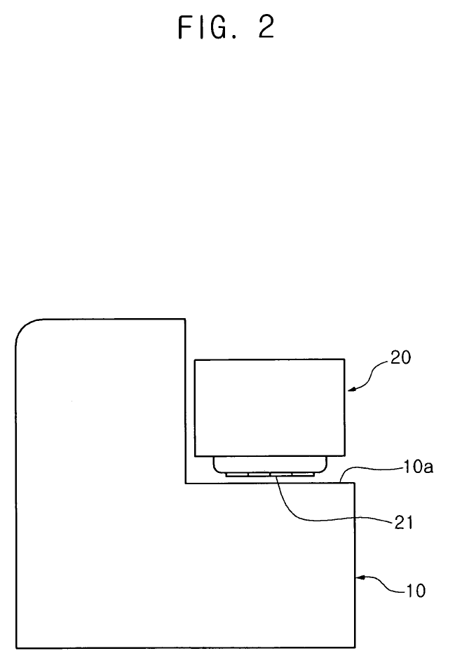

FIG. 1 is a perspective view schematically illustrating an example of the overall structure of a semiconductor device test apparatus according to example embodiments, and FIG. 2 is a side view illustrating the semiconductor device test apparatus shown in FIG. 1, as viewed from one side.

The semiconductor device test apparatus according to example embodiments includes a test handler 10 and a test head 20. Although not shown in either FIG. 1 or FIG. 2, the test handler 10 may include a loading part, an unloading part, and a test part.

In the test handler 10, a plurality of semiconductor devices may be transported by trays. The trays, which may serve as units for transporting the semiconductor devices, may include a customer tray and a test tray. The customer tray may accommodate the semiconductor devices supplied to the test handler 10 before the semiconductor devices are tested and/or may accommodate the semiconductor devices after the semiconductor devices are tested. The test tray may be configured to accommodate the semiconductor devices immediately before, during, and after at testing event. Therefore, a plurality of semiconductor devices to be tested may be accommodated in the customer tray and the customer tray may be loaded in a loading part of the test handler 10.

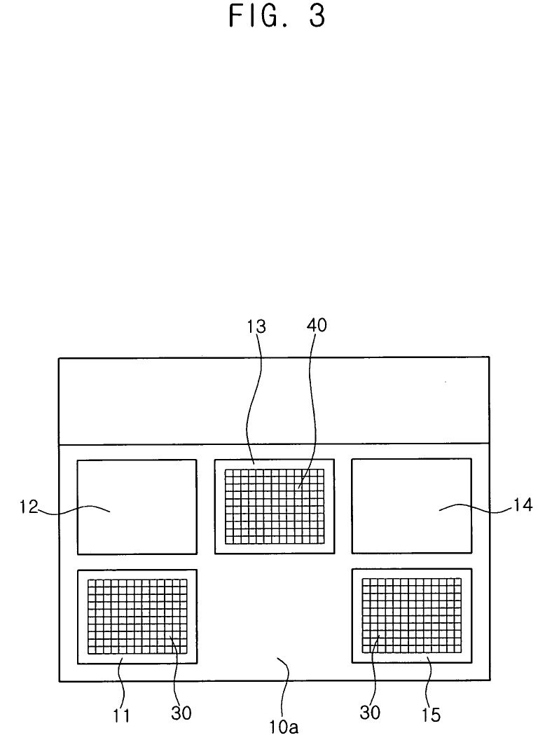

FIG. 3 is a block diagram illustrating an example of a path through which the semiconductor devices may be moved in the test handler according to example embodiments.

As shown in FIG. 3, a plurality of semiconductor devices to be tested is placed in a customer tray 30 which is placed in a loading part 11 of the test handler 10. The customer tray 30 having a plurality of semiconductor devices accommodated therein is moved from the loading part 11 to a soak part 12. In the soak part 12, the semiconductor devices in the customer tray 30 are moved or transported to a test tray 40. The semiconductor devices in the customer tray 30 may be moved to the test tray by overlapping the test tray 40 on an upper surface of the customer tray 30 and rotating the test tray 40 and the customer tray 30. For example, the test tray 40 may be configured to overlap the upper surface of the customer tray 30 and the overlapped trays may be rotated 180 degrees. This operation may result in the test tray 40 and the customer tray 30 being reversed such that the test tray 40 is at a lower part and the customer tray 30 is at an upper part. That is, the operation may result in the test tray 40 being below the customer tray 30. Therefore, the semiconductor devices accommodated in the customer tray 30 may be reversed in the test tray 40.

Although the above description describes the plurality of semiconductor devices as being transferred from the customer tray 30 to the test tray 40 in the soak part 12, example embodiments are not limited thereto. For example, the plurality of semiconductor devices may be moved from the customer tray 30 to the test tray 40 at a location other than the soak part 12. Furthermore, although a method of transferring the plurality of semiconductor chips in the customer tray 30 to the test tray 40 is described, example embodiments are not limited thereto. For example, a robot may be used to individually move chips from a customer tray 30 to a test tray 40 or a robot may be used to move several or all of the semiconductor chips from the customer tray 30 to the test tray 40 simultaneously.

When a plurality of semiconductor devices is transported from the customer tray 30 to the test tray 40 and accommodated in the test tray 40 in the soak part 12, the semiconductor devices in the test tray 40 may be preheated or precooled depending on test environmental conditions.

That is, because the semiconductor devices may be used under various temperature environmental conditions, it may be necessary to test whether the semiconductor devices can be used under the various environmental conditions. Therefore, the semiconductor device may be preheated or precooled so as to be controlled under various environmental conditions.

The semiconductor devices may be preheated or precooled while being accommodated in the test tray 40 and the test tray 40 may be moved to the test part 13.

The test tray 40, having a plurality of semiconductor devices accommodated therein, may be disposed in a test part 13, and the test head 20 may perform an electrical test on the semiconductor devices.

The tested semiconductor devices may be transported to a desoak part 14 while being accommodated in the test tray 40, and the desoak part 14 may remove heat or cold from the semiconductor devices accommodated in the test tray 40 to restore the temperature of the semiconductor devices to room temperature.

The semiconductor devices heated or cooled in the desoak part 14 may be classified and transported from the test tray 40 to the customer tray 30 according to the test results in the test part 13.

In the test part 13 that tests the semiconductor devices while the semiconductor devices are being transported in the test handler 10, the test head 20 may serve as a kind of interface that is electrically connected to a tester (not shown) provided separately from the test part 13 and may transmit or receive electric signals to or from the tester.

As shown in FIG. 2, the test head 20 may include a test socket 21 that may be electrically connected to the external connection terminals of the semiconductor devices accommodated in the test tray 40.

In the test part 13, the test tray 40 may be electrically connected to the test socket 21 of the test head 20 that is provided so as to face the test tray 40.

In the above-mentioned structure, example embodiments illustrate the test head 20 as being above the test handler 10 and the test part 13 is provided on a first surface 10a of the test handler 10 facing the test head 20. That is, in the test part 13, the semiconductor devices in the test tray 40 and the test socket 21 of the test head 20 are electrically connected to each other while facing in the vertical direction. In example embodiments, the external connection terminals of the semiconductor devices in the test tray 40 disposed in the test part 13 are exposed upward.

A contact pusher (not shown) may be provided below the test part 13. The contact pusher may push the lower surface of the test tray 40 disposed in the test part 13 such that the test tray 40 is lifted up to the test head 20, thereby connecting or disconnecting the terminals of the semiconductor devices. However, example embodiments are not limited thereto. For example, a contact pusher may be attached to the test head 20 to move the test head up and down vertically, thereby making contact between the semiconductor devices and the test socket 21.

In example embodiments, the loading part 11, the soak part 12, the test part 13, the desoak part 14, and the unloading part 15 may be formed on the first surface 10a of the test handler 10. However, example embodiments are not limited thereto. For example, only the test part 13 may be formed on the first surface 10a of the test handler 10 and the loading part 11, the soak part 12, the desoak part 14, and the unloading part 15 may be formed on surfaces of the test part 13 other than the first surface 10a.

In example embodiments, the first surface 10a of the test handler 10 on which the test part 13 is formed and the lower surface of the test head 20 on which the test socket 21 is provided may be horizontal planes facing each other, as shown in the drawings. However, the planes facing each other may be inclined at the same angle.

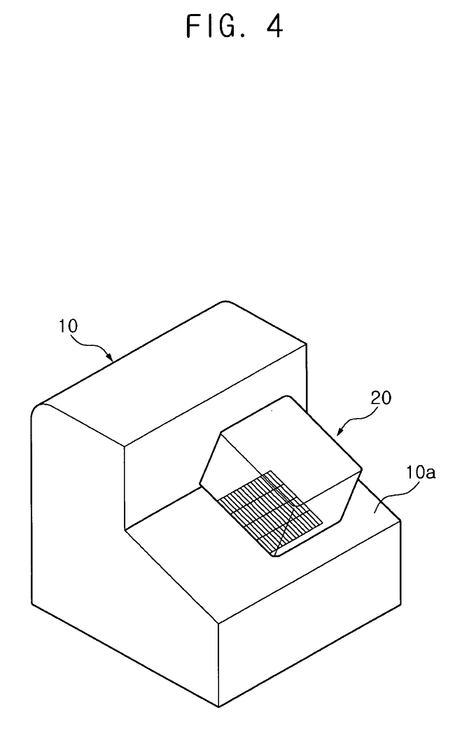

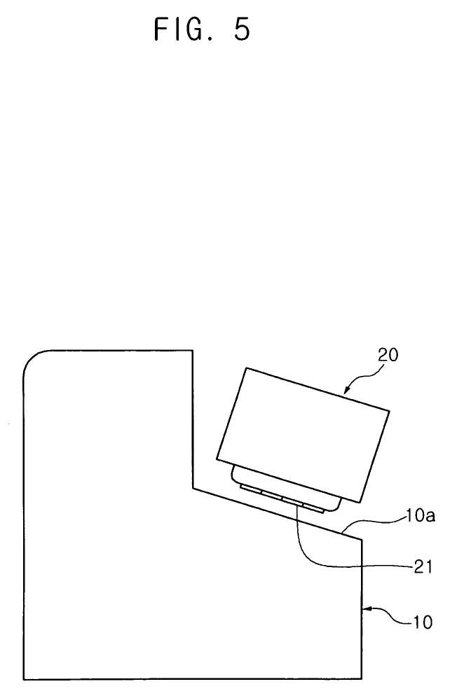

FIG. 4 is a perspective view schematically illustrating the overall structure of a semiconductor device test apparatus according to example embodiments, and FIG. 5 is a side view illustrating the semiconductor device test apparatus shown in FIG. 4, as viewed from one side.

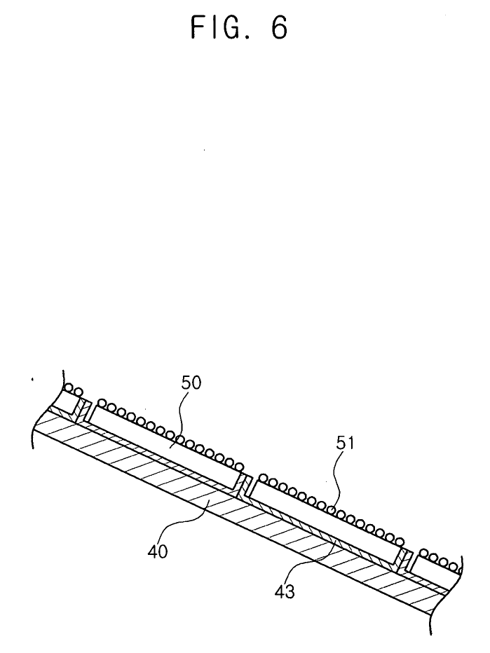

As shown in FIGS. 4 and 5, the first surface 10a of the test handler 10 which faces the test head 20 and on which the test part 13 is formed and the lower surface of the test head 20 on which the test socket 21 is provided may be inclined at the same angle. Therefore, as shown in FIG. 6, the test tray 40 may be inclined at a predetermined or preset angle in the test part 13. In example embodiments, a plurality of semiconductor devices 50 accommodated in the test tray 40 may slide down in mounting holes 41 by their own weight such that the lower surfaces thereof coming into close contact with the test tray 40 may be aligned with each other. When the semiconductor devices are automatically aligned in the test tray 40 in this way, the test head 20 facing the test tray 40 may test the semiconductor devices more accurately.

At least the mounting structure of the test tray 40 may be different from that according to the related art in order to test the semiconductor devices using the semiconductor device test apparatus illustrated in FIGS. 4-6.

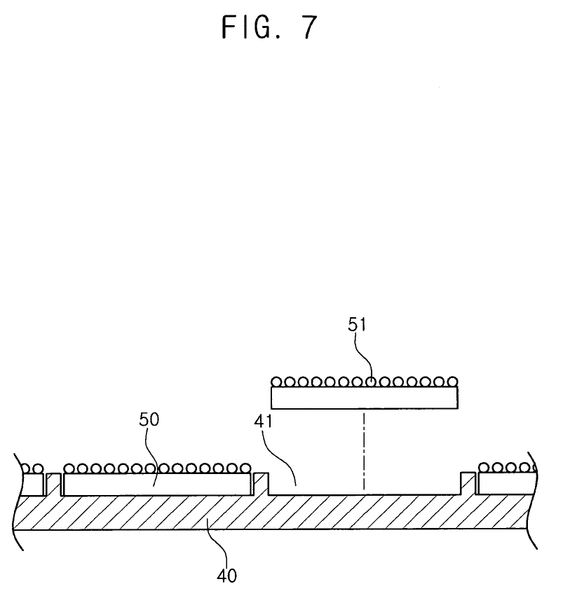

FIG. 7 is a partial enlarged view illustrating an example of the test tray 40 applicable to the semiconductor device test apparatus illustrated in FIGS. 1-6. As shown in FIG. 7, the test tray 40 may be disposed in the test part 13 and the mounting holes 41 are formed with the upper sides opened in order for the external connection terminals 51 of the semiconductor devices 50 accommodated in the test tray 40 to be exposed upward and toward the test head 20. In example embodiments, the size of the top of the mounting hole 41 may be equal to that of the bottom of the mounting hole 41 since there is no concern that the semiconductor devices 50 will be detached during test.

The external connection terminal 51 of the semiconductor devices 50 shown in FIG. 7 may have a ball-type structure using a ball. However, example embodiments are not limited to testing semiconductor devices having the ball type external connection terminals 51. For example, the external terminals may be wires or stubs or various other types of external connectors.

As illustrated in FIG. 6, the test tray 40 according to example embodiments includes mounting holes 41 with upper sides opened to accommodate the semiconductor devices 50. In the test tray 40, the bottom of the mounting hole 41 may be a closed bottom such that the semiconductor device 50 is mounted thereon, or may have a through-hole having a predetermined or preset size.

In the related art, test trays may be required to have a match plate to support a surface corresponding to the surface of the semiconductor device 50 having the external connection terminals 51. However, the test tray 40, according to example embodiments, does not require a match plate, accordingly, a match plate structure may be omitted.

In example embodiments, inserted blocks 43 may be provided in the mounting holes 41 to individually accommodate the semiconductor devices 50. The inserted blocks 43 may be applied as shown in FIG. 6.

In the example semiconductor device test apparatus illustrated in FIGS. 4-5, the first surface 10a may be configured similar to the first surface 10a illustrated in FIGS. 1-3. Therefore, the first surface 10a of the example semiconductor test device apparatus in FIGS. 4-5 may have a first surface 10a having the loading part 11, the soak part 12, the test part 13, the desoak part 14, and the unloading part 15.

In the example semiconductor device test apparatus illustrated in FIGS. 4-5 having the above-mentioned structure, the loading part 11 of the test handler 10 loads the customer tray 30 in which a plurality of semiconductor devices 50 to be tested are accommodated. The semiconductor devices 50 loaded while being accommodated in the customer tray 30 are transported to the test tray 40 and may be placed in various test environments by preheating or precooling the semiconductor devices 50 in the soak part 12. The test tray 40 having the semiconductor devices 50 (that may have been pre-heated or precooled) accommodated therein may be disposed in the test part 13 such that the external connection terminals 51 of the semiconductor devices 50 are exposed toward the test head 20. The test head 20 may be positioned above the test part 13 having the test tray 40 disposed therein. The test socket 21 provided on the lower surface of the test head 20 faces the test tray 40.

In example embodiments, a contact pusher (not shown) may be provided in the test part 13 to push up the test tray 40 from the lower side with the test tray 40 facing the test socket 21 thereby placing the test tray 40 into relatively close contact with the test socket 21 of the test head 20 and thereby connecting the terminals to the test socket 21.

When the tester outputs electric signals with the terminals connected to the test socket 21, the electric signals are applied to the semiconductor devices 50 accommodated in the test tray 40 through the test head 20, thereby checking the electrical characteristics of the semiconductor devices 50.

The test tray 40 may be completely tested and moved from the test part 13 to the desoak part 14, and heat or cold may be removed from the semiconductor devices 50 in the test tray 40 thus restoring the temperature of the semiconductor devices 50 to room temperature.

The semiconductor devices 50 restored to room temperature in the desoak part 14 may be classified and accommodated in customer trays 30 provided in the unloading part 15 according to the test results.

As described above, the semiconductor devices 50 are tested at the first surface 10a of the test handler 10. Because the semiconductor devices are tested at the first surface 10a of the test handler 10, it is possible to omit a structure for preventing the detachment of the semiconductor devices 50 in the test tray 40 from the test handler 10, unlike the related art. That is, in the test apparatus according to the related art, the external connection terminals of the semiconductor devices are formed so as to face the side or downward in the test tray. Therefore, it is necessary to provide the structure for preventing the detachment of the semiconductor devices in the test tray. However, in example embodiments, the external connection terminals 51 of the semiconductor devices 50 may be formed so as to face upward. Therefore, there is no concern that the semiconductor devices will be detached from the test tray 40 during a test. As a result, the structure for preventing the detachment of the semiconductor devices is not needed.

In the horizontal docking structure according to the related art, a test handler and a test head are arranged on the same horizontal plane and the test head moves towards the test handler to dock with the test handler. Therefore, if the size of the test head or the test handler increases, a relatively large area is required for providing the test head and the test handler. In the vertical docking structure according to the related art, a test head is arranged higher than a test handler on one side of the test handler and the test head moves down vertically to dock with the test handler. Therefore, if the size of the test head or the test handler increases, a relatively large area is required for providing the test head or the test handler.

However, according to example embodiments, since the test head 20 is vertically aligned with the test handler 10, an area for providing the test head 20 and the test handler 20 depends on only the size of the test handler. Accordingly, it is possible to improve space efficiency.

Example embodiments may be realized by making minor changes to the arrangement structure of parts of an existing test handler, for example, a loading part, a soak part, a test part, a desoak part, and an unloading part. Therefore, it is possible to minimize or reduce variation in the existing structure.

While the example embodiments have been particularly shown and described, it will be understood by one of ordinary skill in the art that variations in form and detail may be made therein without departing from the spirit and scope of the claims.

What is claimed is:

1. A semiconductor device testing apparatus comprising:
a test head including a test socket configured to contact external terminals of at least one semiconductor device; and
a test handler below the test head, the test handler including a first surface configured to support the at least one semiconductor device so that the external terminals of the at least one semiconductor device are exposed towards the test head.

2. The semiconductor device test apparatus according to claim 1, wherein
the test handler includes a loading part, a soak part, a test part, a desoak part, and an unloading part and at least the test part is on the first surface of the test handler.

3. The semiconductor device test apparatus according to claim 2, wherein the test handler is configured to support a test tray supporting the at least one semiconductor device in the test part.

4. The semiconductor device test apparatus according to claim 2, wherein the test handler is configured to sequentially transport the at least one semiconductor device to the loading part, the soak part, the test part, the desoak part, and the unloading part via a customer tray and a test tray.

5. The semiconductor device test apparatus according to claim 1, wherein
the test head is configured to move towards the first surface of the handler to electrically connect the test socket to the external terminals of the at least one semiconductor device.

6. The semiconductor device test apparatus according to claim 1, wherein
the test handler is configured to move the at least one semiconductor device towards the test head to electrically connect the external terminals of the at least one semiconductor device to the test socket.

7. The semiconductor device test apparatus according to claim 1, wherein the first surface of the test handler and the test head are horizontal.

8. The semiconductor device test apparatus according to claim 1, wherein the first surface of the test handler and the test head are inclined at the same angle.

9. A test system including:
the semiconductor device testing apparatus of claim 1; and
a test tray supported by the test handler, wherein the test tray is configured to support the at least one semiconductor device.

10. The system according to claim 9, wherein the test tray includes at least one mounting hole configured to accommodate the at least one semiconductor device such that the external connection terminals of the at least one semiconductor device are exposed toward the test head.

11. The system according to claim 10, wherein the test tray includes at least one inserted block in the at least one mounting hole to individually accommodate the at least one semiconductor device.

12. The system according to claim 10, wherein a bottom of the at least one mounting hole is closed such that the at least one semiconductor device is mounted thereon.

13. The system according to claim 9, wherein the test handler includes a loading part, a soak part, a test part, a desoak part and an unloading part and at least the test part is on the first surface of the test handler.

14. The system according to claim 13, wherein the test tray is supported in the test part of the handler during a testing operation.

15. The system according to claim 13, further comprising:
a customer tray configured to support the at least one semiconductor device when the at least one semiconductor device is not in the test tray.

16. The system according to claim 15, wherein the test handler is configured to use the customer tray to transport the at least one semiconductor device from the loading part to the soak part, use the test tray to move the at least one semiconductor device from the soak part to the test part, use the test tray to move the at least one semiconductor device from the test part to the desoak part, and use the customer tray to move the at least one semiconductor device from the desoak part to the unloading part.

17. The system according to claim 9, wherein the test head is configured to move towards the first surface of the handler to electrically connect the test socket to the at least one semiconductor device.

18. The semiconductor device test apparatus according to claim 9, wherein the test handler is configured to move the at least one semiconductor device towards the test head to electrically connect the at least one semiconductor device to the test socket.

19. The system according to claim 9, wherein a lower surface of the test socket and the first surface of the test handler are horizontal planes.

20. The system according to claim 9, wherein a lower surface of the test socket and the first surface of the test handler are inclined at the same angle.
